(19) United States
(12) Patent Application Publication
(10) Pub. No.: US 2003/0045091 A1
(43) Pub. Date: Mar. 6, 2003

(54) Method of forming a contact for a semiconductor device

(76) Inventors: In Cheol Ryu, Seoul (KR); Sung Gon Jin, Kyoungki-do (KR)

Correspondence Address: LADAS & PARRY, 224 SOUTH MICHIGAN AVENUE, SUITE 1200, CHICAGO, IL, 60604, US

(21) Appl. No.: 10/034,497

(22) Filed: Dec. 28, 2001

(30) Foreign Application Priority Data
Sep. 5, 2001 (KR) 2001-54511

(51) Int. Cl. H01L 21/4763

(52) U.S. Cl. 438/630

(57) ABSTRACT

A method of forming contact for a semiconductor device is disclosed. The method has the steps of forming a first interlayer dielectric layer on a silicon substrate; forming a conductive material pattern on a portion of the first interlayer dielectric layer; forming a second interlayer dielectric layer over the first interlayer dielectric layer and over the conductive material pattern; forming first and second contact holes by selectively and sequentially removing the second and the first interlayer dielectric layers, the depth of the second contact hole being greater than a depth of the first contact hole, the first contact hole exposing a portion of the conductive material pattern, and the second contact hole exposing a portion of the silicon substrate; forming a glue layer on the first and the second interlayer dielectric layers including over the first and the second contact holes, the glue layer including a CVD TiN layer; and filling the first and the second contact holes with a tungsten layer by forming the tungsten layer on the glue layer.

### BACKGROUND OF THE INVENTION

1. Field of the Invention

The present invention relates generally to a method of fabricating a semiconductor device. More particularly, the present invention relates to a method of forming a contact for a semiconductor device, including a logic device and a memory device, which employs tungsten deposition for a tungsten plug or wiring structure or a tungsten damascene process.

2. Description of the Prior Art

In general, when a contact hole is formed by etching an interlayer dielectric layer, etch source materials used therefor include fluorine. That is, fluorine source gases such as CHF₃, CF₄ and C₂F₈ have been widely used as contact etch source materials in most semiconductor devices. These materials are main etchants for etching a silicon oxide or silicon nitride layer used as the interlayer dielectric layer. In addition, these materials are commonly used together with a plasma etching process for providing a contact etch.

Recent advances in semiconductor integrated circuits have made such devices finer and highly integrated, and consequently, it has become necessary to etch much deeper and smaller contact holes. Furthermore, for reasons of reduction of cost of fabrication, simultaneous etching of various contacts at different positions has become desirable, especially for contact holes having great differences in depth, for example, more than 7000 Å.

Hereinafter, a conventional method for forming contact of a semiconductor device is described with reference to FIG. 1.

Referring to FIG. 1, a first interlayer dielectric layer 3 is deposited on a silicon substrate 1, and then a polysilicon pattern 5 is formed on the first interlayer dielectric layer 3. Next, a second interlayer dielectric layer 7 is deposited over the first interlayer dielectric layer 3 and the polysilicon pattern 5. A photoresist (not shown) is then formed over the second interlayer dielectric layer 7 and the layer 7 is selectively removed by using photolithography technology. Thereby, a photoresist pattern 9 is formed to define first and second contact holes.

Thereafter, by utilizing the photoresist pattern 9 as a mask, the second and first interlayer dielectric layers 7 and 3 are selectively removed. Thus the first and second contact holes 11a and 11b are simultaneously formed, while respectively exposing portions of the polysilicon pattern 5 and the silicon substrate 1. Here the second contact hole 11b has a depth greater than that of the first contact hole 11a. A difference (d) in depth between the contact holes 11a and 11b may be more than 7000 Å.

Due to differences in material where the contact holes are opened or in the depth of the contact holes, the etchant should have a sufficiently high etch selectivity, particularly between silicon in the polysilicon pattern 5 and the oxide in the interlayer dielectric layers 3 and 7, so as to guarantee the desired differences in the thickness of the holes.

However, in the conventional method, a problem arises because the desired shallow contact hole lies uncovered to the etchant until the deep contact hole is completely opened. Unfortunately, this causes variability in the contact hole profile because the etchant reacts with the interlayer dielectric layer exposed to the shallow contact hole. In particular, such variability becomes much more serious near the bottom of the shallow contact hole when the shallow contact hole is located on polysilicon or silicon nitride having a relatively lower etch rate than that of the interlayer dielectric layer.

The undesired variability of contact profile gives rise to difficulties in filling the contact hole and in guaranteeing a stable contact resistance.

### SUMMARY OF THE INVENTION

It is therefore an object of the present invention to provide a method of forming a contact for a semiconductor device capable of obtaining a stable contact resistance by increasing the contact area between conductive material opened within a contact hole and the tungsten filled in the contact hole.

This and other objects are attained in accordance with the present invention by a method of forming a contact for a semiconductor device, the method comprising the steps of forming a first interlayer dielectric layer on a silicon substrate; forming a conductive material pattern on a portion of the first interlayer dielectric layer; forming a second interlayer dielectric layer over the first interlayer dielectric layer and the conductive material pattern; forming first and second contact holes by selectively removing the second and the first interlayer dielectric layers so as to respectively expose a portion of the conductive material pattern and a portion of the silicon substrate; forming a glue layer over the first and the second interlayer dielectric layers including the first and the second contact holes, the glue layer including a CVD TiN layer; and filling the first and the second contact holes with a tungsten layer by forming the tungsten layer on the glue layer.

According to another aspect of the present invention, a method of forming a contact for a semiconductor device, comprises the steps of forming a first interlayer dielectric layer on a silicon substrate; forming a conductive material pattern on a portion of the first interlayer dielectric layer, wherein the conductive material pattern has a lower etch rate than the first interlayer dielectric layer; forming a second interlayer dielectric layer over the first interlayer dielectric layer and over the conductive material pattern; selectively and sequentially removing the second and the first interlayer dielectric layers so as to form first and second contact holes, wherein the second contact hole has a depth greater than the first contact hole, wherein the first contact hole exposes a portion of the conductive material pattern, and wherein the second contact hole exposes a portion of the silicon substrate; forming at least one CVD TiN layer on the first and the second interlayer dielectric layers including over the first and the second contact holes; and forming a tungsten layer on the CVD TiN layer so as to fill the first and the second contact holes.

### BRIEF DESCRIPTION OF THE DRAWINGS

FIG. 1 is a cross-sectional view showing the configuration resulting from performing the steps of a conventional method of forming a contact for a semiconductor device.

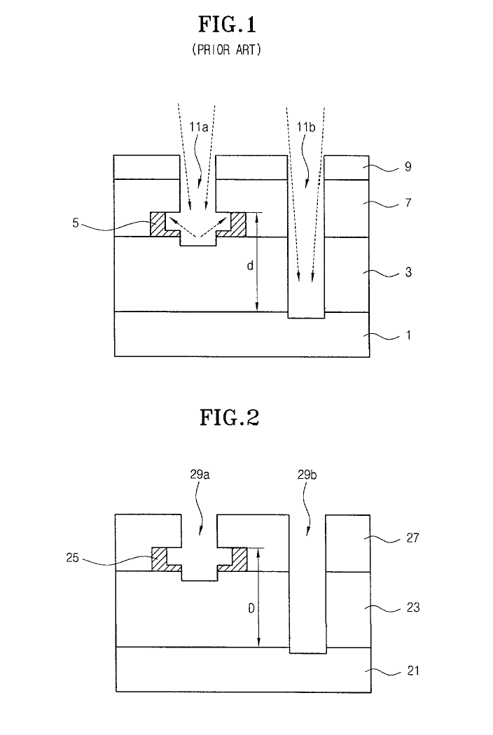

FIGS. 2 to 4 are cross-sectional views showing the steps of a method of forming a contact for a semiconductor device according to an embodiment of the present invention.

### DETAILED DESCRIPTION OF THE INVENTION

The present invention will be now described more fully hereinafter with reference to the accompanying drawings, in which preferred embodiments of the invention are shown.

This invention may, however, be embodied in many different forms and should not be construed as limited to the embodiments set forth herein; rather, these embodiments are provided so that this disclosure will be thorough and complete, and will fully convey the scope of the invention to those skilled in the art.

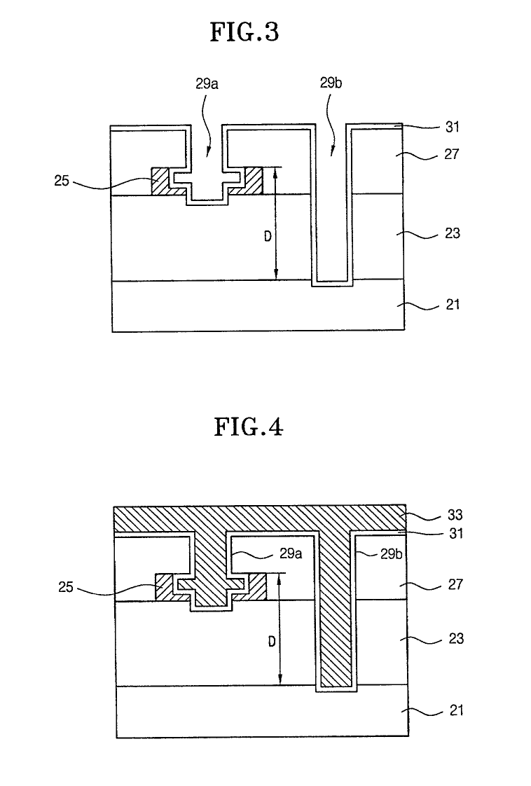

As shown in FIG. 2, a first interlayer dielectric layer 23 is deposited on a silicon substrate 21, and then a conductive material layer (not shown) is formed on the first interlayer dielectric layer 23. The conductive material layer is made of polysilicon, undoped silicon, doped silicon, tungsten silicide or tungsten, preferably having a relatively lower etch rate than that of oxide, boro-phosphorus silicate glass (BPSG) or spin-on-glass (SOG) used for the interlayer dielectric layers 23 and a second layer 27, as is described below.

Next, the conductive material layer is selectively removed to form a conductive material pattern 25. A second interlayer dielectric layer 27 is deposited over the first interlayer dielectric layer 23 and over the conductive material pattern 25. Then, a photoresist (not shown) is formed on the second interlayer dielectric layer 27 and layer 27 is then selectively removed by using a photolithography process. Thereby, the photoresist pattern is formed to define first and second contact holes.

Thereafter, by utilizing the photoresist pattern as a mask, the second and first interlayer dielectric layers 27 and 23 are selectively removed. Thus the first and second contact holes 29a and 29b are simultaneously formed, each respectively exposing portions of the conductive material pattern 25 and of the silicon substrate 21. Here the second contact hole 29b has a depth greater than that of the first contact hole 29a. The difference (D) in depth between both contact holes 29a and 29b is often more than 7000 Å.

The selective removal of the interlayer dielectric layers 23 and 27 is performed by a plasma etching process using a gas, ion or radical having a fluorine source as an etch source. Preferably, the gas having a fluorine source includes CF₄, CHF₃, CH₂F₂, C₂F₆, C₂F₈ or C₅F₈.

As described above in relation to the prior art, the first contact hole 29a having a smaller depth lies uncovered to the etch source until the second contact hole 29b having a greater depth is completely opened. Therefore, the second interlayer dielectric layer 27 exposed to sidewall surfaces of the first contact hole 29a continues to be reacted by the etch source. This causes variability in the contact profile, especially, in the case where the first contact hole 29a, having a smaller depth, is located on the conductive material pattern 25 having a relatively lower etch rate than that of the second interlayer dielectric layer 27. In addition, such variability occurs mostly in the conductive material pattern 25 adjacent the bottom of the first contact hole 29a.

Although the variation of contact profile is produced, the present invention can realize a stable contact resistance by employing a glue layer formed by means of a chemical vapor deposition (CVD) process. Referring to FIG. 3, a thin TiN layer 31 is formed as a preferred glue layer. The TiN layer 31 is conformally deposited on entire exposed surfaces of a resultant structure by the CVD process. That is, the TiN layer 31 is deposited over all of the inner surfaces of the contact holes 29a and 29b, on an exposed surface of the conductive material pattern 25 in the first contact hole 29a, and on the top surface of the second interlayer dielectric layer 27 and around the contact holes 29a and 29b. Preferably, the TiN layer 31 has a thickness of about 400 Å or less. The CVD process for the TiN layer 31 may use a TDMAT, TDMET or TiCl₄ source, each being well known in the art. When a TiCl₄ source is used, a Ti layer or a TiSi₂ layer can be simultaneously deposited with the TiN layer 31. Furthermore, a plasma treatment with RF power under 1 kW can be performed during or after the deposition of the TiN layer 31, while using N₂ and H₂ either together or alone.

Moreover, it is desirable that, to enhance the ability to fill the gap of tungsten in a subsequent process and also to obtain much lower resistance, the glue layer is constituted by a stack structure, which includes the TiN layer formed by the CVD process. For example, the stack structure is composed of Ti, PVD TiN, CVD TiN and W layers or Ti, CVD TiN, PVD TiN and W layers. Here the CVD TiN layer means a TiN layer formed by the CVD process, while the PVD TiN layer means a TiN layer formed by a physical vapor deposition (PVD) process. In addition, and in order to lower contact resistance, an annealing process, such as rapid thermal annealing and tube annealing, can be performed before and after the deposition of the TiN layer 31.

After the TiN layer 31 is formed as the glue layer, the first and second contact holes 29a and 29b are filled in with tungsten. As shown in FIG. 4, a tungsten layer 33 is deposited over the second interlayer dielectric layer 27, including over the contact holes 29a and 29b, so that the contact holes 29a and 29b are completely filled with the tungsten layer 33.

As fully described herein before, a method for forming contact of a semiconductor device according to the present invention has the following advantages. Since the glue layer, such as the CVD TiN layer, provides an improved step coverage for the sidewall surfaces of the contact holes having poor contact profile, the contact area between the conductive material layer and the tungsten layer in the contact holes can be increased. Accordingly, a stable contact resistance can be guaranteed without deviation from a desirable standard range, and further, open failure due to poor contact profile can be prevented. Furthermore, since there is no necessity for performing additional masking and etching processes to solve the problem of poor contact profile, the fabrication process for a semiconductor device can be simplified.

In the drawings and specification, there have been disclosed typical preferred embodiments of the invention and, although specific terms are employed, they are used in a generic and descriptive sense only and not for purposes of limitation, the scope of the invention being set forth in, and only being limited by, the following claims.

What is claimed is:

1. A method of forming a contact for a semiconductor device, comprising the steps of:
forming a first interlayer dielectric layer on a silicon substrate;
forming a conductive material pattern on a portion of the first interlayer dielectric layer;
forming a second interlayer dielectric layer over the first interlayer dielectric layer and over the conductive material pattern;
forming first and second contact holes by selectively removing the second and the first interlayer dielectric layers so as to respectively expose a portion of the conductive material pattern and a portion of the silicon substrate;
forming a glue layer on the first and the second interlayer dielectric layers including over the first and the second contact holes, the glue layer including a CVD TiN layer; and
filling the first and the second contact holes with a tungsten layer by forming the tungsten layer on the glue layer.

2. The method of claim 1, wherein the conductive material pattern comprises a conductive material selected from the group consisting of polysilicon, undoped silicon, doped silicon, tungsten silicide, and tungsten.

3. The method of claim 1, wherein the glue layer further comprises a stack structure of the CVD TiN layers alone or a stack structure of both the CVD TiN layer and a PVD TiN layer.

4. The method of claim 1, wherein the CVD TIN layer is deposited to a thickness of less than about 400 Å by using a TDMAT, TDMET or TiCl₄ source.

5. The method of claim 4, wherein a plasma treatment is further performed during or after the deposition of the CVD TIN layer while using N₂ and H₂ gas either together or alone.

6. The method of claim 1, wherein the CVD TiN layer includes a Ti layer and a TIN layer.

7. The method of claim 1, wherein the step of selectively removing the first and the second interlayer dielectric layers is performed by using a gas, ion or radical having a fluorine source as an etch source.

8. The method of claim 7, wherein the gas having a fluorine source includes CF₄, CHF₃, CH₂F₂, C₂F₆, C₂F₈ or C₅F₈.

9. The method of claim 1, wherein the forming step forms the two contact holes to have a difference in depth between the first and the second contact holes of more than 7000 Å.

10. A method of forming a contact for a semiconductor device, comprising the steps of:
forming a first interlayer dielectric layer on a silicon substrate;
forming a conductive material pattern on a portion of the first interlayer dielectric layer, wherein the conductive material pattern has a lower etch rate than the first interlayer dielectric layer;
forming a second interlayer dielectric layer over the first interlayer dielectric layer and over the conductive material pattern;
selectively and sequentially removing the second and the first interlayer dielectric layers so as to form first and second contact holes, wherein the second contact hole has a depth greater than the first contact hole, wherein the first contact hole exposes a portion of the conductive material pattern, and wherein the second contact hole exposes a portion of the silicon substrate;
forming at least one CVD TiN layer on the first and the second interlayer dielectric layers including over the first and the second contact holes; and
forming a tungsten layer on the CVD TiN layer so as to fill the first and the second contact holes.

11. The method of claim 10, wherein the conductive material pattern is made of a conductive material selected from the group consisting of polysilicon, undoped silicon, doped silicon, tungsten silicide, and tungsten.

12. The method of claim 10, further comprising the step of:
forming a PVD TiN layer after or before the step of forming the CVD TiN layer.

13. The method of claim 10, wherein the CVD TiN layer is deposited with a thickness of less than about 400 Å by using a TDMAT, TDMET or TiCl₄ source.

14. The method of claim 13, wherein a plasma treatment is further performed during or after the deposition of the CVD TiN layer while using N₂ and H₂ gas either together or alone.

15. The method of claim 10, wherein the CVD TiN layer includes a Ti layer and a TiN layer.

16. The method of claim 10, wherein the step of selectively and sequentially removing the second and the first interlayer dielectric layers is performed by using gas, ion or radical having a fluorine source as an etch source.

17. The method of claim 16, wherein the gas having fluorine source includes CF₄, CHF₃, CH₂F₂, C₂F₆, C₂F₈ or C₅F₈.

18. The method of claim 10, wherein the removing step selectively removes the dielectric layers so as to provide contact holes having a difference in depth between the first and the second contact holes of more than 7000 Å.

19. The method of claim 10, further comprising the step of:
performing a rapid thermal annealing process or a tube annealing process after or before the step of forming the CVD TiN layer.
